(19) United States
(12) Patent Application Publication
(10) Pub. No.: US 2005/0026425 A1
(43) Pub. Date: Feb. 3, 2005

(54) Semiconductor device manufacturing method

(75) Inventor: Katsuhiro Hakata, Tsukuba (JP)

Correspondence Address: Stanley P. Fisher;Reed Smith LLP, Suite 1400, 3110 Fairview Park Drive, Falls Church, VA, 22042-4503, US

(73) Assignee: Trecenti Technologies, Inc.

(21) Appl. No.: 10/900,429

(22) Filed: Jul. 28, 2004

(30) Foreign Application Priority Data
Jul. 29, 2003 (JP) JP2003-282140

(51) Int. Cl. H01L 21/4763

(52) U.S. Cl. 438/645

(57) ABSTRACT

The CMP of laminated heterogeneous metal films is efficiently improved without changing the structure of a conventional CMP apparatus. The CMP of a portion where heterogeneous metal films are laminated is performed on the same platen of a CMP apparatus having a single-platen structure. These heterogeneous metal films are a first layer metal film made of a wiring conductive metal such as Cu, and a second layer metal film made of a barrier film conductive metal such as Ti or Ta. After the CMP of the first layer metal film by using a slurry for polishing the first layer metal film is performed, the wafer is retracted from a polishing pad within a polishing unit of the CMP apparatus. With this state, the polishing pad is cleaned and then the retracted wafer is returned. Then, the CMP of the second layer metal film is performed by supplying a slurry for polishing the second layer metal film. By providing the process of cleaning the polishing pad between the process of polishing of the first layer metal film and the process polishing of the second layer metal film, the CMP can be efficiently performed with a single-platen structure even if the slurry for polishing the first layer metal film and the slurry for polishing the second layer metal film have much different properties.

### CROSS-REFERENCE TO RELATED APPLICATION

The present application claims priority from Japanese patent application No. JP 2003-282140 filed on Jul. 29, 2003, the content of which is hereby incorporated by reference into this application.

### BACKGROUND OF THE INVENTION

The present invention relates to a technique for manufacturing a semiconductor device and, more particularly, to a technique effectively applied to a Chemical Mechanical Polishing (CMP) process of a wiring metal film and a barrier metal film that are laminated mutually.

As a wiring technique in a method of manufacturing a semiconductor device, there is a technique for performing, by using slurry, the CMP of a barrier conductive metal film made of tantalum (Ta), titanium (Ti), or the like and a wiring conductive metal film made of copper (Cu) or the like that is laminated on the barrier conductive metal film.

In such CMP of the laminated metal films, a first layer metal film (an upper-layer metal film), which is the wiring conductive metal film, and a second layer metal film (a lower-layer metal film), which is a barrier conductive metal film located lower than the first layer metal film, are separately polished.

As CMP apparatuses, there are a plural-platen apparatus having a plurality of platens for polishing and a single-platen apparatus having a single platen. In the plural-platen apparatus, the plurality of platens are appropriately used, and the different platens are used for first layer metal film polishing and second layer metal film polishing, whereby the CMP is performed.

Meanwhile, in the single-platen apparatus having a single platen, a wafer is once taken out from the CMP apparatus after the first layer metal film polishing is completed. Then, a polishing pad of the platen used for the first layer metal film polishing is cleaned. Then, the wafer taken out from the CMP apparatus is again returned to the inside of the apparatus, and then the polishing pad having been used for the first layer metal film polishing is used for the second layer metal film polishing.

Alternatively, instead of polishing both of the heterogeneous metal films by using a single CMP apparatus, the CMP apparatus different per metal film may be exclusively used for each metal film in some cases. A CMP apparatus for first layer metal film and a CMP apparatus for second layer metal film are respectively provided for polishing. Also in this case, after polishing of the first layer metal film is completed, the wafer is taken out from the CMP apparatus for first layer metal film and is then transferred separately to the CMP apparatus for second layer metal film, whereby the second layer metal film is polished.

In this way, even if either of the plural-platen apparatus or the single-platen apparatus is used as the CMP apparatus, the CMP of the heterogeneous of metal films adopts a multistage polishing method by dividing the first layer metal film polishing and the second layer metal film polishing. In contrast, there has been proposed a technique of the consistent polishing through one process without dividing the CMP into a plurality of steps by adopting a fixed abrasive-coating method (Japanese Patent Laid-open No. 2002-324772 (hereinafter “Patent Document 1”)).

Also, as for the consistent polishing through one process, there has been proposed a method of performing the CMP, in which ferric nitrate slurry and oxalic acid that have the same proper pH range at the time of using the same platen are respectively used for tungsten (W) polishing and for titan (Ti) polishing of a barrier film (Japanese Patent Laid-open No. 10-270399 (hereinafter “Patent Document 2”)).

### SUMMARY OF THE INVENTION

Now, in the above-described CMP of the above-mentioned laminated heterogeneous metal films, the inventor of the present invention has noticed the following problems.

That is, in recent years, the diameter of a wafer has been increased and a product line facility supporting such increase has been demanded accordingly. As the diameter of the wafer increases, an area to be polished in the CMP increases and the polishing process at speed higher than ever is demanded.

However, since the polishing speed is defined mainly in combination with the metal to be polished and the polishing slurry, it is impossible to easily increase the speed merely in accordance with the increase in the wafer diameter from the viewpoint of improvement of the polishing speed. Consequently, an idea of increasing a throughput of the CMP apparatus is necessarily drawn.

Changing the structure of the apparatus itself is one way to achieve the high throughput. However, this can never be an effective measure in an apparatus's economical point of view. On the premise of the structure of the CMP apparatus described thus far, if the high throughput is to be achieved by changing its utilization, the high throughput can be realized without new investment in facilities such as replacement of the CMP apparatus and its related appliances.

The inventor has thought it is important to achieve the high throughput by considering how the CMP apparatus having the conventional structure is efficiently used.

The inventor has studied in detail the polishing procedures performed in the well-known CMP apparatus. Further, the inventor has examined in detail the polishing procedures performed in both structures of the plural-platen apparatus and the single-platen apparatus including the structures disclosed in the above-mentioned Patent Documents 1 and 2.

The examination has been made not only from the viewpoints of whether the high throughput can be achieved but also from the viewpoint of quality of polishing in the CMP. Through the examination, the inventor has realized that various types of slurries are commercially available for the CMP of the laminated heterogeneous metal films in accordance with the types of the metals to be polished and, depending on combination of the slurry and its corresponding metal, it is necessary to change various polishing conditions such as a pressing force of the wafer surface to the polishing pad and a polishing speed. The inventor has keenly realized again such a large variety of polishing conditions in the CMP.

Furthermore, in the semiconductor device manufacturing field, in accordance with a variety of product demands, it is desired to flexibly support limited production of a wide variety of products in place of conventional mass production of one type. The same is true of the CMP. That is, there is desired a technique for appropriately fulfilling various CMP conditions by using the CMP apparatuses having the same structure and for being capable of contributing to the limited production of a wide variety of products. Currently, however, those conditions do not seem to be sufficiently fulfilled.

For example, Patent Document 1 discloses an excellent technique that can certainly achieve a high throughput by performing consistent polishing in comparison with the conventional method of performing the polishing by dividing into multistage. However, this adopts the fixed abrasive-coating method and therefore cannot be applied to a CMP process, which uses different abrasive coatings for each heterogeneous metal film at the time of the CMP. To use different abrasive coatings, a free abrasive-coating method is preferable.

In the free abrasive-coating method of performing the CMP by supplying the abrasive coating containing predetermined slurry onto the polishing pad, different abrasive coatings such as alumina, colloidal silica, and fumed silica can be used per laminated metal film. Therefore, a variety of combinations of abrasive coatings, which is one aspect of variation desired for the CMP, can be sufficiently provided.

Also, unlike the technique of the Patent Document 1, the Patent Document 2 discloses the CMP of laminated metal films, which is performed by adopting a free abrasive-coating method. The Patent Document 2 discloses the CMP method under such special conditions that, by assuming that a Ti film or the like is used as an underlying metal film and a W film is used as an upper metal film, slurries for the Ti film and the W film have the same property whose a proper pH range is less than 2 at the time of their uses.

It is true that such a technique is particularly excellent in that an optimum slurry is selectively used for each heterogeneous metal film by adopting the free abrasive-coating method in place of the fixed abrasive-coating method and the optimum polishing is performed. However, in the case of the structure in which the slurries having the same proper pH range at the time of their uses are utilized, the CMP using slurries different in property such as liquid property cannot be sufficiently performed.

In the field of CMP of the heterogeneous metal films, using slurries having different properties is not so rare but is a very common practice. It is therefore desired to appropriately use the different slurry properties such as liquid properties, that is, acidic and alkaline properties, or proper pH ranges even if their liquid properties are the same.

An object of the present invention is to improve polishing efficiency in performing the CMP of the laminated heterogeneous metal films without changing the structure of the conventional CMP apparatus.

The above and other objects and novel characteristics will become apparent from the description of the specification and the accompanying drawings.

Outlines of the representative ones of inventions disclosed in the present application will be briefly described as follows.

In a semiconductor device manufacturing method according to the present invention, the CMP of the laminated heterogeneous metal films is performed on the polishing pad provided to the platen. By interposing the pad cleaning process therebetween, the slurries having different properties such as liquid properties are used for the CMP of the heterogeneous metal films.

Effects of the representative ones of inventions disclosed in the present invention will be briefly described as follows.

It is possible to improve polishing efficiency in performing the CMP of the laminated heterogeneous metal files without changing the structure of the conventional apparatus.

### BRIEF DESCRIPTION OF THE DRAWINGS

FIG. 1 is a plan view schematically showing a CMP apparatus having a single-platen structure, which is used in an embodiment of the present invention.

FIG. 2 is a side view schematically showing a principal portion of a polishing unit in a CMP apparatus used in the embodiment of the present invention.

FIG. 3A is a section view showing a principal portion of a place where heterogeneous metal films to perform the CMP are laminated in a procedure applied in the embodiment of the present invention.

FIG. 3B is a section view showing a principal portion of a laminated state of the heterogeneous metal films.

FIG. 4A is a section view showing a principal portion of planarization achieved by a CMP procedure applied in the embodiment of the present invention.

FIG. 4B is a section view showing a principal portion in a state of forming a cap film on a Cu film.

FIG. 5A is a flow diagram showing a procedure applied in the embodiment of the present invention.

FIG. 5B is a flow diagram showing a procedure applied in the embodiment of the present invention.

FIG. 5C is a flow diagram showing a procedure applied in the embodiment of the present invention.

FIG. 5D is a flow diagram showing a procedure applied in the embodiment of the present invention.

FIG. 6 is an explanatory diagram for describing a state in which a slurry is changed while the state of CMP is being maintained.

FIG. 7 is a plan view schematically showing the entirety of a CMP apparatus having a plural-platen structure, which is used in the embodiment of the present invention.

FIG. 8 is an explanatory diagram for describing effects on throughputs of the present invention in graph form.

FIG. 9 is an explanatory diagram for describing effects on polishing quality relating to particle adhesion and scratches in graph form according to the present invention.

FIG. 10 is an explanatory diagram for describing effects on wafer defects in graph form according to the present invention.

FIG. 11 is an explanatory diagram for describing effects on Cu contamination in graph form according to the present invention.

FIG. 12 is a plan view schematically showing the entirety of a CMP apparatus having a plural-platen structure, which is used in the embodiment of the present invention.

FIG. 13A is a flow diagram of a procedure applied in the embodiment of the present invention by a CMP apparatus having a plural-platen structure.

FIG. 13B is a flow diagram of a procedure applied in the embodiment of the present invention by a CMP apparatus having a plural-platen structure.

### DESCRIPTION OF THE PREFERRED EMBODIMENTS

Hereinafter, embodiments of the present invention will be detailed based on the drawings. Note that the same members are denoted by the same reference symbol in principle throughout all the drawings for describing the embodiments and the repetitive explanation thereof will be omitted.

(First Embodiment)

In the present embodiment, description will be made of a semiconductor device manufacturing method having a CMP process of laminated heterogeneous metal films, by using a CMP apparatus having a single-platen structure.

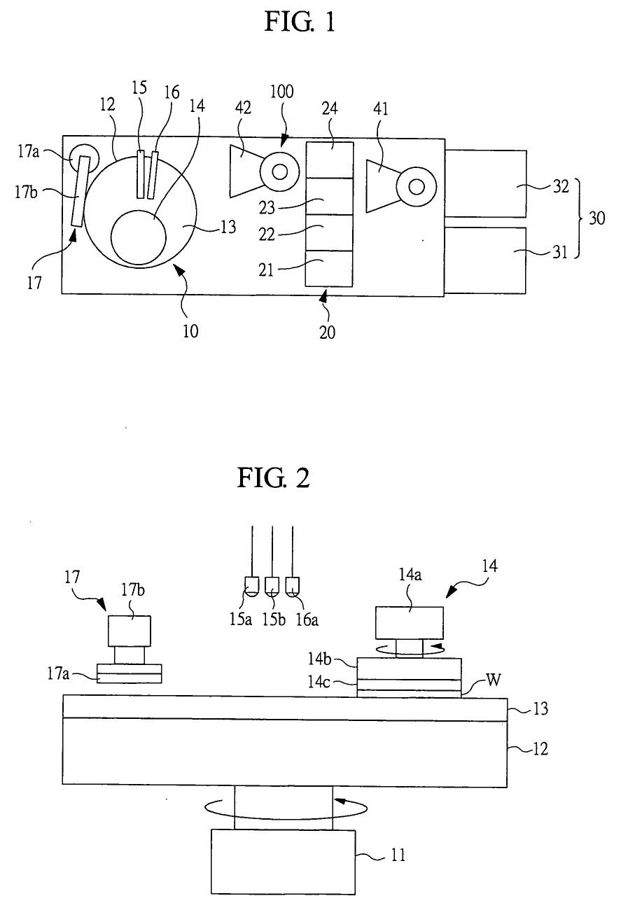

FIG. 1 is a plan view schematically showing the entirety of a CMP apparatus having a single-platen structure, which is used in an embodiment of the present invention. FIG. 2 is a side view schematically showing a principal portion of a polishing unit in a CMP apparatus.

A CMP apparatus 100 having a single-platen structure is provided with, as shown in FIG. 1, a polishing unit 10 and a cleaning unit 20 therein. In addition to them, a carrying-in/out unit 30 for reception and delivery of a wafer from and to the outside of the apparatus is also provided. Inside the apparatus, as shown in FIG. 1, robots 41 and 42 are provided for reception and delivery of the wafer between the cleaning unit 20 and the carrying-in/out unit 30 and between the polishing unit 10 and the cleaning unit 20, respectively.

In the polishing unit 10, as shown in FIG. 2, a platen (also called as a surface plate) 12 to be rotated by a motor 11 is provided with a polishing pad 13. A head mechanism section 14 is provided for rotatably holding a wafer W with respect to the surface of the polishing pad 13. The head mechanism section 14 can place a polishing surface of the wafer W so that the polishing surface is opposite via a carrier pad 14c to a wafer carrier 14b rotated by a motor 14a.

Also, above the polishing pad 13, there are provided: slurry supply ports 15a and 15b connected to a slurry supply line 15 of a plurality of supply lines; and a cleaning fluid supply port 16a connected to a polishing pad cleaning fluid supply line 16. As occasion demands, a required slurry or a polishing pad cleaning fluid can be separately supplied.

Meanwhile, a pad conditioner 17 is provided to hold vertical-movably a rotatable dresser 17a at a tip of an arm 17b. In conditioning the polishing pad 13, the dresser 17a can be moved, by the arm 17b, from a waiting position on a side of the polishing pad 13, to the polishing pad 13.

In the cleaning unit 20, as shown in FIG. 1, a ultrasonic cleaning unit 21, brush cleaning units 22 and 23, and a drying unit 24 are provided in respective separate rooms. Wafer cleaning can be sufficiently performed after the CMP is completed.

Meanwhile, the carrying-in/out unit 30 includes, as shown in FIG. 1, a carrying-in port 31 for carrying the wafer to be polished from the outside of the apparatus, and a carrying-out port 32 for carrying the wafer cleaned and dried by the cleaning unit to the outside of the apparatus after the CMP is completed.

Next, description will be made of a semiconductor device manufacturing method having a process of the CMP of the laminated heterogeneous metal films by using the above-structured CMP apparatus 100 having the single-platen structure.

First, an element such as a MOSFET is formed on a main surface of a p-type Si wafer. An interlayer dielectric is then formed so as to cover the element formed on the main surface. A contact hole is formed on the interlayer dielectric and then a plug is formed inside of the contact hole.

After the plug is formed, a conductor film made of tungsten (W) or the like is deposited through spattering. On the deposited conductor film, dry etching is performed by using a resist film as a mask to form a first layer wiring. Then, a SiO₂ film (a silicon oxide film), a thin silicon nitride film, and a SiO₂ film are sequentially deposited in this order by a plasma CVD method.

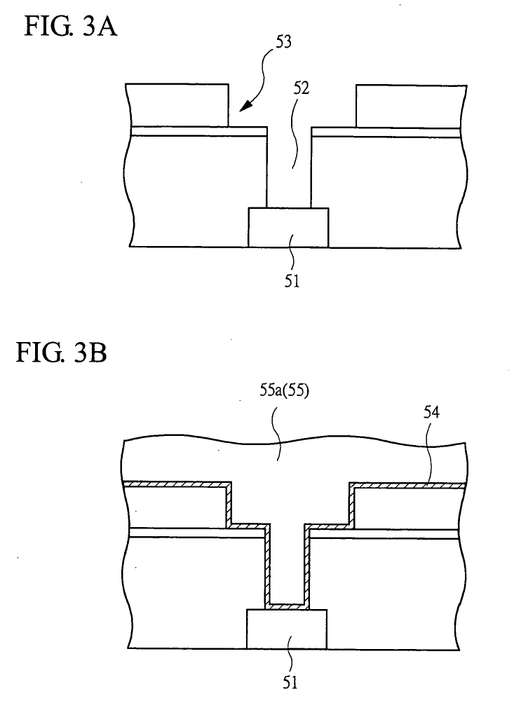

To such laminated films, as shown in FIG. 3A, a through hole 52 leading to a first layer wiring 51 and a wiring trench 53 are formed by using a resist film as a mask. The through hole 52 and the wiring trench 53 are filled with Cu by, for example, a dual damascene method to form a second layer wiring.

Such Cu embedding is performed in such a manner that, as shown in FIG. 3B, a conductive metal film 54 made of, for example, tantalum (Ta) or titanium nitride (TiN) or the like used as a barrier film is deposited in the through hole 52 and the wiring trench 53 by spattering and then a Cu film 55a (55) is deposited as a conductive metal film 55 for forming the second layer wiring. In this way, in the through hole 52 and the wiring trench 53, the conductive metal film 54 made of Ta or the like and the conductive metal film 55 such as the Cu film 55a are laminated, thereby becoming in a state that heterogeneous metal films are laminated.

Note that, in the following description of the CMP, the conductive metal film 55 such as the Cu film 55a may be referred to as a first layer metal film and the conductive metal film 54 may be referred to as a second layer metal film in some cases.

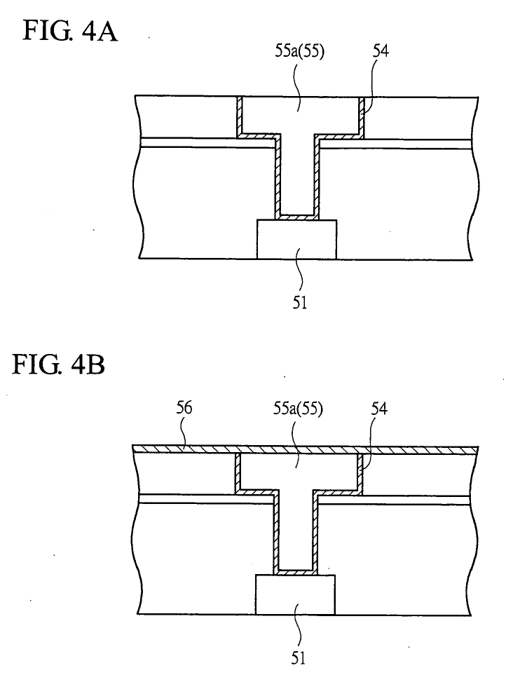

With this state, the above-described CMP apparatus 100 is used to remove unnecessary portions of the conductive metal film 54 for the barrier film and the Cu film 55a, which are deposited on an insulating film through the CMP, thereby achieving planarization as shown in FIG. 4A.

After the planarization through the CMP is completed, as shown in FIG. 4B, a cap film 56 is formed on the second layer wiring by using a silicon nitride film or the like. Then, the same process as that for forming the second layer wiring is repeated to form a plurality of Cu-embedded wirings used as a third layer wiring and layer wirings subsequent thereto. The last wiring layer is formed of aluminum, and a bump electrode or the like is formed thereon.

In the process of forming the above-mentioned Cu-embedded wiring, the above-described CMP apparatus 100 is used to perform the CMP based on the processing procedure according to the present invention, which is described below. By adopting a processing procedure different from that described thus far, a high throughput in the CMP can be achieved without changing the structure of the apparatus.

Through the Cu embedding process as described above in the previous stage, the wafer becomes in such a state that the conductive metal film 54 as the barrier film and the Cu film 55a are deposited in the through hole 52 and the wiring trench 53. The predetermined number of such wafers is accommodated in a transferring wafer cassette, and is then transferred by a transferring means such as a robot to the carrying-in port 31 of the CMP apparatus 100.

From the transferred wafer cassette, the wafers are taken out one by one by the robot 41 and are passed to the robot 42. The robot 42 transfers the received wafer to the wafer carrier 14b constituting the head mechanism section 14 of the polishing unit 10. In the wafer carrier 14b, a chuck means for vacuum absorption or the like absorbs the back surface of the wafer via the carrier pad 14c and holds the polishing surface so as to be opposed to the surface of the polishing pad 13 on the platen 12, whereby the polishing of the Cu film 55a is prepared.

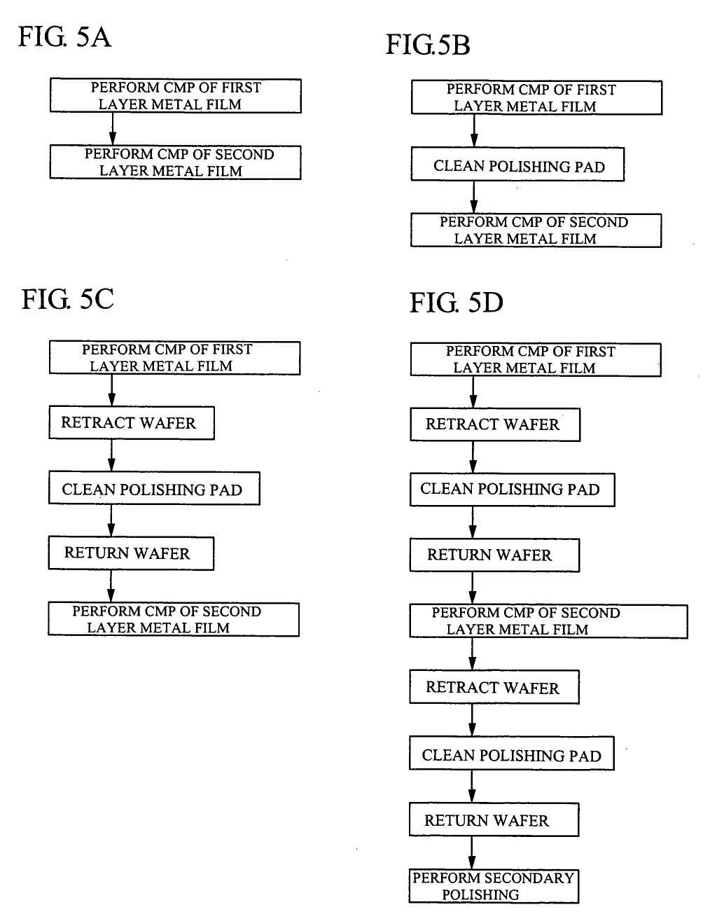

FIG. 5A is a flow diagram showing the processing procedure of the CMP described in the present embodiment. The first layer metal film (Cu film) is polished in the following manner, as shown in FIG. 5A. That is, a slurry for polishing the first layer metal (a previous polishing slurry for metal to be polished first) is supplied from the slurry supply port 15a onto the polishing pad 13 rotated at the predetermined number of rotations, which satisfies conditions suitable for polishing the first layer metal. In addition to this, the wafer held by the wafer carrier 14b and rotated at the predetermined number of rotations, is pressed, by predetermined pressure, onto the polishing pad 13 and then the CMP is performed.

First, at the polishing pad 13 on the platen 12, the Cu film 55a that is the first layer metal film is polished through the CMP. When a polishing end point of the first layer metal film is detected by a time, a change in polishing speed, or the like, the supply of the slurry for the first layer metal film polishing is stopped.

When the supply of the slurry for the first layer metal film polishing is stopped, a slurry for the second layer metal film polishing (a subsequent polishing slurry for metal to be polished later) is supplied from the slurry supply port 15b onto the polishing pad 13. Even at the time of switching the supply from the slurry for the first layer metal film polishing to the slurry for the second layer metal film polishing, the wafer is continuously pressed onto the polishing pad 13 while held by the wafer carrier 14b and rotated.

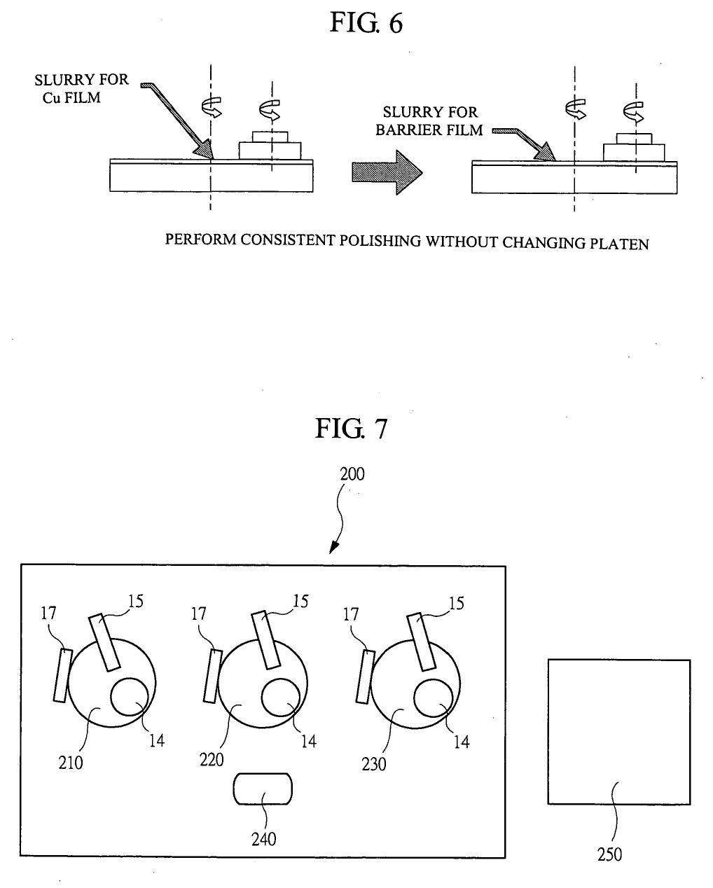

Since wafer polishing is continuously switched from the slurry for the first layer metal film polishing to the slurry for the second layer metal film polishing, the polishing of the second layer metal film is switched from the polishing of the first layer metal film, continuously, that is, without any interruption. Such a state is shown in FIG. 6. In the case of FIG. 6, a slurry for the Cu film as the slurry for the first layer metal film polishing and a slurry for a barrier film as the slurry for the second layer metal film polishing are shown, respectively.

Therefore, as compared with a CMP processing procedure in which polishing is forced to be interrupted, a much higher throughput can be achieved. In the conventional CMP processing procedure, when the polishing unit 10 completes the CMP of the first layer metal film, the wafer is once separated from the polishing pad 13 by the head mechanism section 14 and is then passed to the robot 42.

Then, the wafer subjected to a series of cleaning and anticorrosive processes by the cleaning unit 20 is passed to the robot 41 and delivered to the outside of the CMP apparatus 100 and kept waiting. During that, on a side of the platen 12, the polishing pad 13 is cleaned. When the cleaning is completed, the wafer is returned to the polishing pad 13 of the CMP apparatus 100 and the CMP of the second layer metal film is performed.

In the processing procedure according to the present embodiment, as described above, the supply of the polishing slurry is switched without taking the wafer out to the outside of the CMP apparatus 100 while the wafer is maintained in the polishing state. Therefore, a much higher throughput can be achieved.

Also, once the wafer is taken out to the outside of the apparatus, the cleaning process is required. However, such a cleaning process is not required in the procedure according to the present embodiment because the wafer is not taken out to the outside of the apparatus. This also contributes to the achieving of the high throughput. Since the cleaning process can be omitted, the used amount of cleaning chemical liquid can also be reduced.

In the present embodiment, the CMP of the first layer metal film and that of the second layer metal film are continuously performed in the same CMP apparatus 100. Therefore, it is possible to reduce a time required for processing a dummy wafer for lamp-up of the apparatus before processing the wafer. Additionally, it is possible to reduce the used amount of consumable agents such as a slurry used in the dummy wafer process. Depreciation costs of the dummy wafer can be also reduced. Still further, in view of cost effectiveness of the apparatus, it is possible to contribute to reduction of the disposing number of CMP apparatuses.

In view of product quality, such an effect of omitting the cleaning process also contributes to reduction in product defects such as scratch in the cleaning process.

In the continuous CMP of such laminated heterogeneous metal films, the slurry for the first layer metal film polishing and the slurry for the second layer metal film polishing may both be acidic or alkaline and have the same liquid property. However, even though they have the same liquid property, each may have a different proper pH range. As disclosed in the Patent Document 2, the slurries in this embodiment do not have to have the same proper pH range.

When the slurries to be used are acidic, it is more preferable that the slurry for the second layer metal film polishing is lower in proper pH range than that for the first layer metal film polishing. That is, it is preferable that the slurry for the second layer metal film polishing is more acidic than that for the first layer metal film polishing.

The reason is as follows. At the time of the slurry-switching from the slurry for the first layer metal film polishing to the slurry for the second layer metal film polishing, a state of mixture of these slurries for the first and second layer metal film polishing temporarily occurs. However, if the degree of acidity of the slurry for the second layer metal film polishing is higher, it is possible to more suppress influence of the slurry for the first layer metal film polishing onto the second layer metal film polishing after the first layer film polishing is completed.

For the same reason, when the slurries to be used are alkaline, it is preferable that the degree of alkalinity of the slurry for the second layer metal film polishing is higher than that for the first layer metal film polishing.

In the above description, the case of using the CMP apparatus 100 having the single-platen structure is exemplarily described. However, for example, a CMP apparatus 200 having a plural-platen structure as shown in FIG. 7 can be used.

In the CMP apparatus 200, as shown in FIG. 7, a polishing unit and a cleaning unit are separately provided as apparatuses. In the polishing unit, three platens, that is, a first platen 210, second platen 220, and third platen 230, are provided to perform the CMP separately per platen.

Conventionally, in the above-structured CMP apparatus 200, polishing of the second layer metal film is performed at the second platen for a short period of polishing time, and polishing of the first layer metal film is performed at the first and third platens disposed on both side thereof for a long period of polishing time. The wafer after the first layer metal film polishing is completed is transferred by a transferring means such as a robot 240, to the second platen 220 alternately from the both-side platens, whereby the second layer metal film is polished.

By adopting such a process for transferring the wafer after polishing of the first layer metal film is completed to the second platen 220 alternately from the both-side platens, the cleaning process and the CMP process are synchronized with each other. That is, it is possible to prevent the wafer after the second layer metal film has been polished from being accumulated between the CMP step and the cleaning step due to an excess of the amount of the CMP process over the capability of the cleaning process.

By the use of the above-structured CMP apparatus 200, the continuous CMP in the present embodiment can be performed to all the platens attached to the apparatus. Thus, the continuous CMP processes can be concurrently performed as many as the number of platens. That is, the CMP in the procedure shown in FIG. 5A is concurrently performed at each of the first platen 210, the second platen 220, and the third platen 230.

After the CMP is competed in the CMP apparatus 200, the wafer is transferred by a transferring means such as a robot to a cleaning apparatus 250 separately provided, and then the cleaning process after the CMP is performed.

Note that, to perform the above concurrent processes using the CMP apparatus 200, the same continuous CMP process is started per platen in a time-shifted manner, whereby the synchronization between the cleaning process and the CMP process can be achieved. Therefore, there is no need to increase the number of cleaning apparatuses in accordance with the concurrent processes performed by the plural platens.

(Second Embodiment)

In a second embodiment, unlike the structure described in the above first embodiment, description will be made of a CMP process in which a process of cleaning the polishing pad is provided between the process of the first layer metal film polishing and the process of the second layer metal film polishing. With the process of cleaning the polishing pad, the continuous CMP can be performed using the slurry for the second layer metal film polishing, which is completely different in its property from the slurry for the first layer metal film polishing. This CMP can be performed using the CMP apparatus 100 described in the first embodiment.

FIG. 5B is a flow diagram showing a processing procedure of the CMP described in the present embodiment. The first layer metal film is polished in the following manner, as shown in FIG. 5B. That is, the slurry for the first layer metal film polishing is supplied from the slurry supply port 15a onto the polishing pad 13 rotated at the predetermined number of rotations that satisfies conditions suitable for polishing the first layer metal film. Also, while the wafer held by the wafer carrier 14b is also rotated at the predetermined number of rotations, it is pressed by the predetermined pressure onto the polishing pad 13 and then the CMP is performed.

Thus, at the polishing pad 13 on the platen 12, the Cu film 55a that is the first layer metal film is first polished through the CMP. When a polishing end point of the first layer metal film is detected by a time, a change in polishing speed, or the like, the supply of the slurry for the first layer metal film polishing to the surface of the polishing pad 13 is stopped.

When the supply of the slurry for the first layer metal film polishing is stopped, a polishing pad cleaning fluid is supplied from the cleaning fluid supply port 16a through the polishing pad cleaning fluid supply line 16 and the slurry for the first layer metal film polishing, which is supplied onto the surface of the polishing pad 13, is cleaned. After the slurry for the first layer metal film polishing is cleaned, the slurry for the second layer metal film polishing is supplied from the slurry supply port 15b.

Even at the time of switching a sequence of processes for stopping the supply of the slurry for the first layer metal film polishing, supplying the polishing pad cleaning fluid and stopping its supply, and supplying the slurry for the second layer metal film polishing, the wafer is pressed onto the polishing pad 13 while held and rotated by the wafer carrier 14b and the polishing of the wafer is continued. Also in the present embodiment, as described above, the polishing state of the wafer is maintained during the process of the first layer metal film polishing to the second layer metal film polishing. Therefore, as compared with the CMP procedure in which the polishing is forced to be interrupted, the much higher throughput can be achieved.

In the structure of the present embodiment, the wafer is polished in such a manner that, after the first layer metal film polishing is completed, the slurry for the first layer metal film polishing is cleaned by the polishing pad cleaning fluid and then the slurry for the second layer metal film polishing is supplied. Therefore, unlike the structure of the first embodiment and the structure disclosed in the Patent Document 2, the structure of the second embodiment can be effectively applied to the case where the slurry for the first layer metal film polishing is much different in its property from the slurry for the second layer metal film polishing.

In this regard, an appropriate time period for the polishing process is 1 to 100 seconds in view of the entire processing time. Also, a commercially-available cleaning fluid can be used as the polishing pad cleaning fluid such as one manufactured by Wako Pure Chemical Industries, Ltd.

To clean the polishing pad 13, pure water may be used as the polishing pad cleaning fluid. Alternatively, polishing pad cleaning fluid that is different from pure water in chemical liquid's composition may be used as long as the liquid does not affect the second layer metal film polishing. In the present embodiment, the polishing pad is cleaned while the CMP is continued with the wafer being pressed onto the polishing pad. Therefore, pure water is preferably used as the polishing pad cleaning fluid.

In the present embodiment, the process of cleaning the polishing pad is involved. Therefore, the procedure of the present embodiment can be effectively applied to, for example, the case where one of the slurry for the first layer metal film polishing and the slurry for the second layer metal film polishing is acidic and the other is alkaline. Also, the procedure can be effectively used when the abrasive coating used in the slurry for the first layer metal film polishing are different from that used in the slurry for the second layer metal film polishing. Furthermore, the procedure can be applied when the slurry for the first layer metal film polishing and the slurry for the second layer metal film polishing are much different from each other in both liquid properties and abrasive coatings. Such applications cannot be achieved in the first embodiment and the technique disclosed in the Patent Document 2.

Also, it is preferable to apply the procedure of the present embodiment rather than that of the first embodiment when the slurry for the first layer metal film polishing is extremely higher in the degree of acidity than the slurry for the second layer metal film polishing and is extremely larger in the used amount even though these slurries have the same liquid properties, that is, when “pH of the slurry for the first layer metal film polishing”<<“pH of the slurry for the second layer metal film polishing”.

When a Cu film is assumed as the first layer metal film, a commercially-available slurry can be used as the slurry for the first layer metal film polishing. Also as the slurry for the second layer metal film polishing, a commercially-available slurry can be used.

In the processing procedure according to the present embodiment, as described above, the supply of the polishing slurry is switched without taking the wafer out to the outside of the CMP apparatus 100 with the polishing state being maintained. Therefore, a much higher throughput can be achieved.

Furthermore, once the wafer is taken out to the outside of the apparatus, the cleaning process is required. However, such a cleaning process is not required in the procedure according to the present embodiment because the wafer is not taken out to the outside of the apparatus. This also contributes to achieving of the high throughput. Since the cleaning process can be omitted, the used amount of cleaning chemical liquid can be reduced.

In the present embodiment, the CMP of the first layer metal film and that of the second layer metal film are continuously performed in the same CMP apparatus 100. Therefore, it is possible to reduce a time required for processing a dummy wafer for lamp-up of the apparatus before processing the wafer. Also, it is possible to reduce the used amount of consumable substances such as slurries used in the dummy wafer process. Furthermore, depreciation cost of the dummy wafer can be reduced. Still further, in view of cost effectiveness of the apparatus, it can contribute to reduction in the number of CMP apparatuses disposed. In view of product quality, such an effect of omitting the cleaning process also contributes to reduction in product defects such as scratches generated in the cleaning process.

In the above description, the case of using the CMP apparatus 100 having the single-platen structure is used has been exemplarily described. However, for example, the CMP apparatus 200 having the plural-platen structure as shown in FIG. 7 can be used in the manner as described in the first embodiment. That is, by using the CMP apparatus 200, all the platens attached thereto can perform the continuous CMP in the procedure shown in FIG. 5B, and the same continuous CMP processes can be concurrently performed as many as the number of platens.

Similarly to the first embodiment, in order to perform the above concurrent processes, the same continuous CMP process is started per platen in a time-shifted manner, whereby the synchronization between the cleaning process and the CMP process can be achieved. There is no need to increase the number of cleaning apparatuses in accordance with the concurrent processes performed by the plural platens.

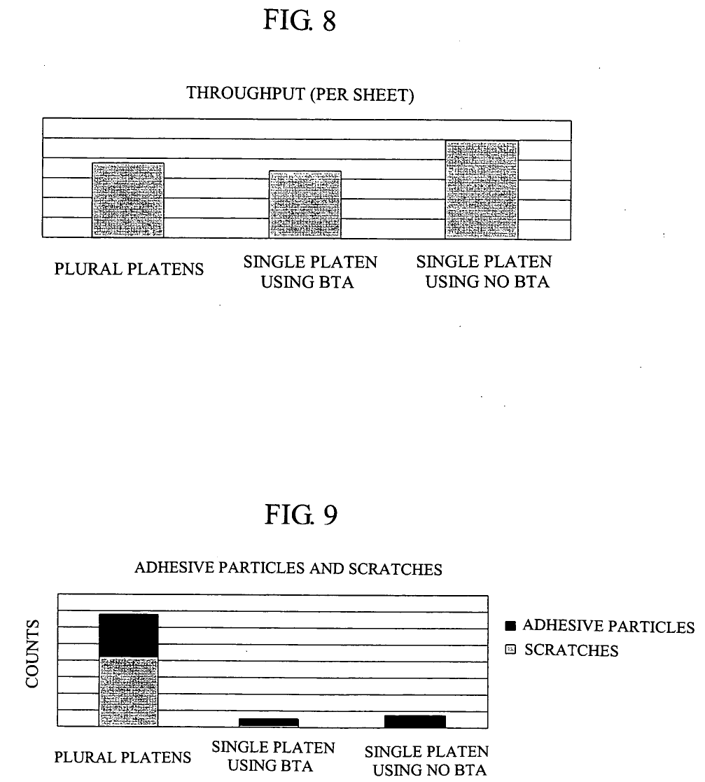

As for an increase of the throughput based on the CMP processing procedure according to the present embodiment, as shown FIG. 8, under the same polishing conditions of the heterogeneous metal films to be polished and of the slurries to be used and the like, it is possible to achieve a throughput 1.3 times higher than the throughput obtained in the case of using the CMP apparatus having the plural platens.

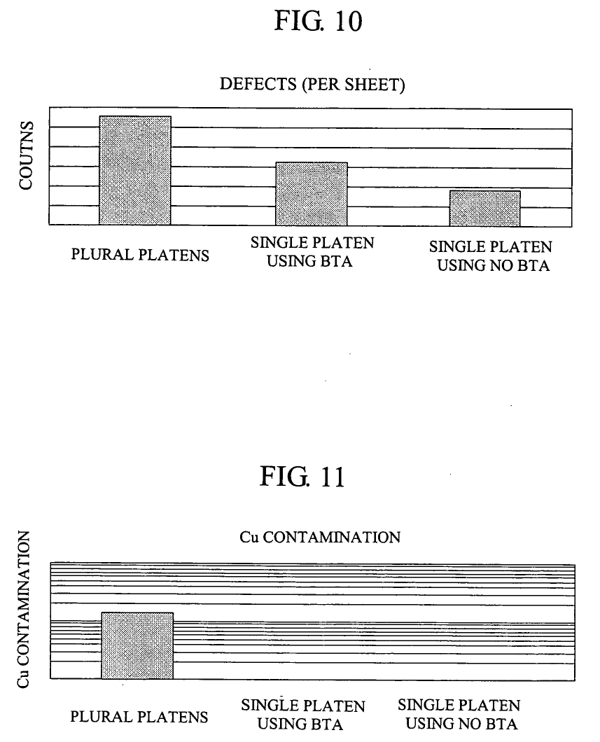

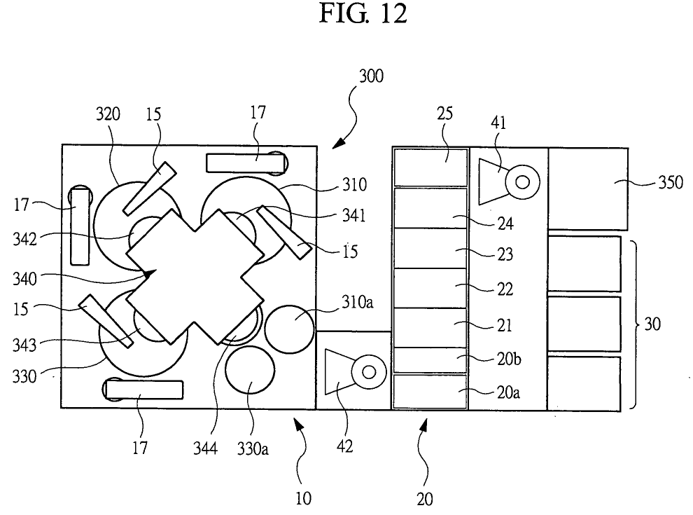

As for the polishing quality by the CMP, as shown in FIG. 9, adhesive particles and the number of scratches are reduced to approximately one tenth of those in the case of using the CMP apparatus having the plural platens. Wafer defects can be reduced, as shown in FIG. 10, to approximately one third and contamination by Cu dispersion can be reduced, as shown in FIG. 11, by one to two orders of magnitude, in comparison with the case of using the CMP apparatus having the plural-platen structure.

(Third Embodiment)

In the first and second embodiments, description has been made of the continuous CMP in which the wafer is in contact with the polishing pad and is continuously in a polishing state during the process of the first layer metal film polishing to the second layer metal film polishing. However, in a third embodiment, description will be made of the case where a process of temporarily retracting the wafer from the polishing pad is interposed after the process of the first layer metal film polishing is completed and before the process of the second layer metal film polishing is started.

FIG. 5C is a flow diagram showing a processing procedure of the CMP described in the present embodiment. The first layer metal film is polished in the following manner, as shown in FIG. 5C. That is, the slurry for the first layer metal film polishing is supplied from the slurry supply port 15a onto the polishing pad 13 rotated at the predetermined number of rotations that satisfies conditions suitable for polishing the first layer metal film. Also, the wafer held by the wafer carrier 14b is also rotated at the predetermined number of rotations and is pressed by the predetermined pressure onto the polishing pad 13 under such a condition and the polishing of the CMP is performed.

Thus, at the polishing pad 13 on the platen 12, the Cu film 55a that is the first layer metal film is first polished through the CMP. When a polishing end point of the first layer metal film is detected by a time, a change in polishing speed, or the like, the wafer carrier 14b goes up so that the polishing surface of the wafer is separated from the polishing pad 13.

Then, with the wafer being held by the wafer carrier 14b, the surface of the first layer metal film is subjected to an anticorrosive process with BTA of 0.01% to 1%, and is temporarily retracted. During its temporary retraction, the wafer waits in the polishing room while held by the wafer carrier 14b. If it is assumed that a Cu film is used as the first layer metal film, such an anticorrosive process with the use of BTA takes about 1 to 100 seconds.

While the wafer is being temporarily retracted, the supply of the slurry for the first layer metal film polishing is stopped and the cleaning fluid is supplied from the cleaning fluid supply port 16a through the polishing pad cleaning fluid supply line 16 and the slurry for the first layer metal film polishing is swept from the surface of the polishing pad 13. After the slurry for the first layer metal film polishing is swept away, the slurry for the second layer metal film polishing is supplied from the slurry supply port 15b.

Note that the wafer is temporarily retracted to a position where the wafer is not subject to splashes etc. of the polishing pad cleaning fluid for polishing the polishing pad 13.

Then, the temporarily-retracted wafer is again moved to the polishing pad 13 and is rotated at the predetermined number of rotations, which satisfies conditions suitable for polishing the second layer metal film, and is then returned to the polishing pad 13 to which the slurry for the second layer metal film polishing is supplied from the slurry supply port 15b. Also, the wafer held by the wafer carrier 14b is rotated at the predetermined number of rotations and is pressed by the predetermined pressure onto the polishing pad 13 and the CMP of the second layer metal film is performed.

Such a series of processes of the CMP of the laminated heterogeneous metal films is performed in such a manner that the first layer metal film polishing and the second layer metal film polishing are performed by using the polishing pad 13 of the same platen 12. However, unlike the conventional procedure in which the wafer is once taken out to the outside of the apparatus, the wafer is temporarily retracted within the polishing room.

In the present embodiment, the wafer polishing is performed in such a manner that, after the first layer metal film polishing is completed, the wafer is temporarily retracted in a state of being subjected to an anticorrosive process. Then, the slurry for the second layer metal film polishing is supplied in such a state that the slurry for the first layer metal film polishing is cleaned by the polishing pad clearing fluid during the retraction of the wafer. Therefore, as compared with the case of the second embodiment in which the polishing pad is cleaned while the wafer polishing process is continued, the quality of cleaning of the polishing pad is high, whereby an excellent effect is achieved in view of the quality after the CMP is completed.

Also, it is possible to prevent the polishing pad cleaning fluid from affecting the process of polishing the second layer metal film. Furthermore, in addition to cleaning of the polishing pad, the polishing pad 13 may be subjected to the conditioning of the pad conditioner 17.

Unlike the first embodiment and the technique disclosed in the Patent Document 2, the present embodiment can be effectively applied to the case where the slurry for the first layer metal film polishing and the slurry for the second layer metal film polishing have much different slurry properties.

For example, the present embodiment can be effectively applied to the case where one of the slurry for the first layer metal film polishing and the slurry for the second layer metal film polishing is acidic and the other is alkaline. Also, it can be effectively used when the abrasive coating used in the slurry for the first layer metal film polishing are different from that used in the slurry for the second layer metal film polishing. Furthermore, it can be applied when the slurry for the first layer metal film polishing and the slurry for the second layer metal film polishing are much different in both liquid properties and abrasive coatings. Such applications cannot be achieved in the first embodiment and the technique disclosed in the Patent Document 2.

The CMP including the retracting process described in the present embodiment is particularly effective when the remaining state of the slurry for the first layer metal film polishing or a polishing complex formed by the slurry and the first layer metal film may affect the process of the second layer metal film polishing even in trace proportions.

In the above description, the case of using the CMP apparatus 100 having the single-platen structure has been exemplarily described. However, for example, the CMP apparatus 200 having the plural-platen structure, as shown in FIG. 7, may be used. In the CMP apparatus 200, all the platens attached thereto can perform the continuous CMP described in the present embodiment, and the same continuous CMP processes can be concurrently performed as many as the number of platens.

Similarly to the first embodiment, in order to perform the above concurrent processes, the same continuous CMP process is started per platen in a time-shifted manner, whereby the synchronization between the cleaning process and the CMP process can be achieved. There is no need to increase the number of cleaning apparatuses in accordance with the concurrent processes performed by the plural platens.

As for effects obtained by adopting the processing procedure according to the present embodiment, as shown in FIG. 8, since the anticorrosive process using BTA is performed, the throughput is inferior to that in the case of using the CMP apparatus having the plural-platen structure or the single-platen structure without performing such an anticorrosive process. However, as shown in FIGS. 9, 10, and 11, the polishing quality in the CMP is significantly superior to that in the case where the CMP apparatus having the plural platens.

As shown in FIG. 9, adhesive particles and scratches are reduced to less than approximately one tenth (1/10) of those in the case of using the CMP apparatus having the plural-platen structure. Also, as shown in FIG. 10, wafer defects can be reduced to approximately one second (½) and, as shown in FIG. 11, contamination by Cu dispersion can be reduced by one to two orders of magnitude in comparison with the case of using the CMP apparatus having the plural-platen structure.

As shown in FIG. 5D, an exemplary application of the present embodiment may be one in which: after the second layer metal film polishing is completed, the wafer is retracted in the same manner as that taken after the first layer metal film polishing; the polishing pad is cleaned during its retraction; and then secondary polishing is performed by using a finishing polishing slurry, which is different from the slurry for the first layer metal film polishing and the slurry for the second layer metal film polishing. With such secondary polishing, it is possible to repair scratches, dishing, and erosion without taking measures of, for example, providing separately a platen for secondary polishing.

(Fourth Embodiment)

In a fourth embodiment, description will be made of a method of performing the continuous CMP by using the CMP apparatus having the plural-platen structure. In the present embodiment, a CMP apparatus 300 having a structure as shown in FIG. 12 is used.

As shown in FIG. 12, the CMP apparatus 300 includes, similarly to the CMP apparatus 100 shown in FIG. 1, the polishing unit 10, the cleaning unit 20, and the carrying-in/out unit 30. Similarly thereto, for reception and delivery of the wafer, the robots 41 and 42 are also provided.

The polishing unit 10 has a first platen 310, a second platen 320, and a third platen 330 that are fixedly provided on the same circumference centering on a rotational head mechanism section 340, thereby forming a plural-platen structure. A polishing wafer station 310a and a polishing-completed wafer station 330a are provided at locations where the wafer is received from and delivered to the robot 42, respectively.

The rotational head mechanism section 340 is provided with wafer carriers 341, 342, 343, and 344, each of which can be rotated by a motor and be vertically moved separately. By the rotation of the rotational head mechanism section 340, each of the wafer carriers 341, 342, 343, and 344 can sequentially go around the first platen 310, the second platen 320, and the third platen 330, which are positioned and fixed, at a certain tact time.

Above each platen, a polishing pad is provided, and a slurry supply line 15 for supplying a polishing slurry onto the polishing pad and a pad conditioner 17 for conditioning the polishing pad are provided, respectively.

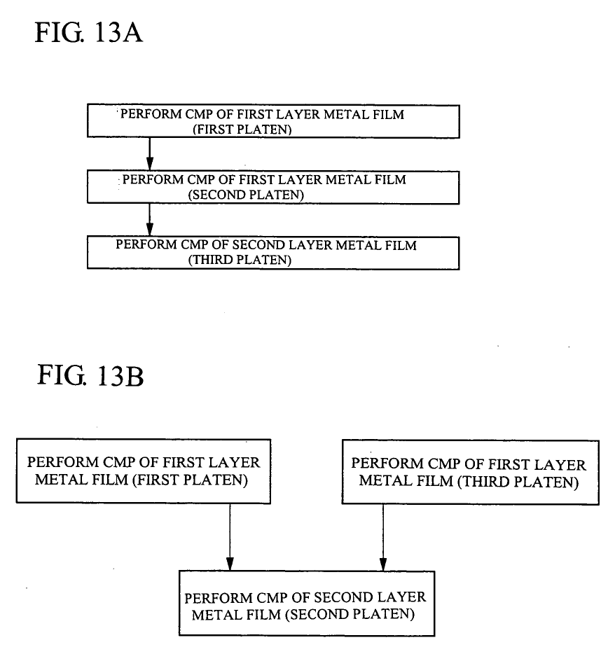

FIG. 13A is a flow diagram showing a processing procedure of the CMP using the above-structured CMP apparatus 300. The CMP is performed to the first metal film in the following manner. That is, the slurry for the first layer metal film polishing is supplied from the slurry supply line 15 onto the polishing pad, which is disposed on the first platen 310 and is rotated at the predetermined number of rotations that satisfies conditions suitable for polishing the first layer metal film. Also, the wafer held by the wafer carrier 341 is rotated at the predetermined number of rotations and is pressed by the predetermined pressure onto the polishing pad in such a state, and the CMP is performed.

Thus, at the polishing pad on the first platen 310, the Cu film 55a that is the first layer metal film is polished through the CMP. After the first layer metal film is polished for a predetermined time, the wafer carrier 341 goes up and the wafer is separated from the first platen 310. Then, the rotational head mechanism section 340 is rotated and the wafer is moved onto the second platen 320, and then the wafer carrier 341 goes down and is pressed by the predetermined pressure onto the polishing pad, whereby the predetermined CMP is performed.

Then, at the second platen 320, the CMP of the first layer metal film is continuously performed. When the polishing is completed, similarly to the above-described processing procedure, the wafer is separated from the polishing pad of the second platen 320 by the rotation of the rotational head mechanism section 340 and is moved to the third platen 330. Then, polishing of the second layer metal film is performed on the polishing pad of the third platen 330. The CMP of the first layer metal film is performed in a separate manner on the first platen 310 and the second platen 320. This is because a tact time of rotation of the rotational head mechanism section 340 is made to coincide with a short processing time for the second layer metal film polishing in a time required for the CMP.

When polishing of the second layer metal film at the third platen 330 is completed, the wafer is moved from the third platen 330 to the polishing-completed wafer station 330a by the rotational head mechanism section 340. The wafer carrier 341, which has finished moving the wafer, holds a new wafer at the polishing wafer station 310a and is again moved to the first platen 310 to perform the CMP of the first layer metal film.

In this way, at each of the wafer carriers 341, 342, 343, and 344, the following processes are sequentially repeated: holding the wafer to be polished; polishing the first layer metal film at the first platen 310; polishing the first layer metal film at the second platen 320; polishing the second layer metal film at the third platen 330; and passing the wafer to the polishing-completed wafer station. As such, the CMP is performed by the CMP apparatus 300 having the plural-platen structure in a sheet-feeding manner.

In the present embodiment, as shown in FIG. 13A, at the first platen 310, the second platen 320, and the third platen 330, the wafer is separated without a process for supplying water, which has been given in the conventional CMP process. Therefore, as compared with other CMP processes with the same plural-platen structure, a higher throughput can be achieved by omitting such a process for supplying water.

Thus, after a series of processes for the CMP of the first layer metal film and the second layer metal film is completed, the wafer is moved to the polishing-completed wafer station 330a and is delivered by the robot 42 to the cleaning unit 20. In the cleaning unit 20, the wafer goes via an input station 20a, a pass through 20b, the ultrasonic cleaning unit 21, the brush cleaning units 22 and 23, and the drying unit 24 to an output station 25.

From the output station 25, the wafer after the cleaning process is delivered by the robot 41 from a port of the carry-in/out unit 30 to the outside of the apparatus, and is transferred to the next process. Before the wafer is delivered to the outside of the apparatus, a film thickness measuring unit 350 examines whether the film after the CMP has the predetermined thickness.

The wafers are carried to the CMP apparatus 300 in such a manner that the wafers are taken out by the robot 41 one by one, from a wafer cassette carried to the carrying-in/out unit 30, and passed to the robot 42, and passed from the robot 42 to each wafer carrier 341 etc.

As shown in FIG. 13B, the processing procedure described in the present embodiment, in which the wafer is separated from the polishing pad without supplying water thereto, can be carried out also through the CMP apparatus 200 shown in FIG. 7. That is, this procedure can be applied when the wafer is separated from each polishing pad of the first platen 210, the second platen 220, and the third platen 230. Therefore, a high throughput can be achieved in the CMP using the CMP apparatus 200.

As described above, the inventions made by the inventor have been concretely described based on the above embodiments. However, needless to say, the present invention is not limited to the foregoing embodiments and can be variously modified and altered without departing from the gist thereof.

For example, the above description has been exemplarily made of the case where the Cu film is used as the first layer metal film. However, of course, the present invention can be applied to metal such as W and Al (aluminum) other than Cu.

Also, the above description has been exemplarily made of the case where the heterogeneous metal films are laminated to form two layers. However, of course, the present invention can be applied to the case of laminating three or more layers. For example, the present invention can be applied to the case where two different metal films are laminated to form a barrier film and a wiring metal film(s) is laminated thereon.

The polishing slurry is not restricted to a slurry including abrasive coatings, but a water slurry may be used.

The present invention can be effectively used, for example, in a field of manufacturing semiconductor devices such as memories, system LSIs, liquid crystal LCDs, and storage disks, which require the CMP of the heterogeneous metal films.

1. A semiconductor device manufacturing method comprising the step of:
polishing, through a chemical mechanical polishing method, heterogeneous metal films laminated on a semiconductor wafer,
wherein the polishing of said heterogeneous metal films to be laminated is performed by:
on the same platen, supplying, to a polishing pad, a previous polishing slurry for a metal film to be first polished, and polishing the metal film;
cleaning said polishing pad; and
thereafter, supplying a subsequent polishing slurry, which is different in a property from said previous polishing slurry, and then performing a metal film to be later polished.

2. The semiconductor device manufacturing method according to claim 1,
wherein said previous polishing slurry and said subsequent polishing slurry are different in at least one of a liquid properties and an abrasive coating.

3. The semiconductor device manufacturing method according to claim 2,
wherein said polishing pad is cleaned by using pure water or a pad cleaning fluid.

4. The semiconductor device manufacturing method according to claim 2,
wherein said polishing pad is cleaned and is subjected to conditioning.

5. The semiconductor device manufacturing method according to claim 2,
wherein, the metal film to be first polished out of said heterogeneous metal films is a copper film.

6. The semiconductor device manufacturing method according to claim 1,
wherein, between polishing by using said previous polishing slurry and polishing by using said subsequent polishing slurry, said semiconductor wafer is retracted from said platen and said polishing pad is cleaned.

7. A semiconductor device manufacturing method comprising the step of:
polishing, through a chemical mechanical polishing method, heterogeneous metal films laminated on a semiconductor wafer,
wherein the polishing of said heterogeneous metal films to be laminated is performed by:
supplying, to a polishing pad on the same platen, a previous polishing slurry for a metal film to be first polished, and polishing the metal film; and
thereafter, supplying a subsequent polishing slurry, which is different in a property from said previous polishing slurry, and then performing a metal film to be later polished.

8. The semiconductor device manufacturing method according to claim 7,
wherein said previous polishing slurry and said subsequent polishing slurry are the same in a liquid property and are different in at least one of a pH range and an abrasive coating.

9. The semiconductor device manufacturing method according to claim 8,
wherein, the metal film to be first polished out of the heterogeneous metal films to be polished through said chemical mechanical polishing method is a copper film.

10. A semiconductor device manufacturing method having a process of polishing, through a chemical mechanical polishing method, heterogeneous metal films laminated on a semiconductor wafer, by using a polishing apparatus having plural platens, the method comprising the steps of:
supplying a previous polishing slurry for the metal film to be first polished out of said heterogeneous metal films, to a first polishing pad provided on a first platen;
polishing the metal film to be first polished on said semiconductor wafer;
after the polishing, separating said semiconductor wafer from said first platen and moving it on another platen other than said first platen;
supplying a subsequent polishing slurry for the metal film to be later polished out of said heterogeneous metal films, to a polishing pad provided on another platen other than said first platen; and
polishing a metal film to be polished after said semiconductor wafer.

11. The semiconductor device manufacturing method according to claim 10,
wherein said first platen and the another platen other than said first platen are set as a plurality of platens that a chemical mechanical polishing apparatus has.

12. The semiconductor device manufacturing method according to claim 10,
wherein said metal film to be later polished is polished by supplying, to the another polishing pad provided on the another platen other than said first platen, a subsequent polishing slurry that is the same liquid property as said previous polishing slurry and is different from said previous polishing slurry in a pH range proper at the time of use

13. The semiconductor device manufacturing method according to claim 10,
wherein the metal film to be first polished out of said heterogeneous metal films is a copper film.
